(19) United States
(12) Patent Application Publication
(10) Pub. No.: US 2015/0258466 A1
(43) Pub. Date: Sep. 17, 2015

(54) SEPARATION AND REGENERATION APPARATUS AND SUBSTRATE PROCESSING APPARATUS

(71) Applicant: Tokyo Electron Limited, Tokyo (JP)

(72) Inventors: Kazuyuki Mitsuoka, Yamanashi (JP); Hiroki Ohno, Yamanashi (JP); Takehiko Orii, Yamanashi (JP); Takayuki Toshima, Kumamoto (JP)

(21) Appl. No.: 14/644,344

(22) Filed: Mar. 11, 2015

(30) Foreign Application Priority Data
Mar. 13, 2014 (JP) 2014-050876

(51) Int. Cl. B01D 3/10; H01L 21/67

(52) U.S. Cl. CPC B01D 3/10; H01L 21/67023

(57) ABSTRACT

Disclosed is a separation and regeneration apparatus including: a mixed drainage liquid tank (mixed liquid generating unit) configured to generate a mixed liquid which includes a low-specific-gravity liquid insoluble in a fluorine-containing organic solvent, a first fluorine-containing organic solvent having a first boiling point, and a second fluorine-containing organic solvent having a second boiling point higher than the first boiling point; a distillation tank configured to separate the first fluorine-containing organic solvent and the second fluorine-containing organic solvent in the mixed liquid into the first fluorine-containing organic solvent in a gas state and the second fluorine-containing organic solvent in a liquid state; a first tank configured to liquefy and store the first fluorine-containing organic solvent from the distillation tank; and a second tank configured to store the second fluorine-containing organic solvent from the distillation tank.

### CROSS-REFERENCE TO RELATED APPLICATIONS

This application is based on and claims priority from Japanese Patent Application No. 2014-050876, filed on Mar. 13, 2014, with the Japan Patent Office, the disclosure of which is incorporated herein in its entirety by reference.

### TECHNICAL FIELD

The present disclosure relates to a separation and regeneration apparatus and a substrate processing apparatus used to remove a liquid attached to the surface of a substrate by using a high-pressure fluid in a supercritical state or a subcritical state.

### BACKGROUND

In a fabricating process of a semiconductor device in which a lamination structure of an integrated circuit is formed on a surface of a semiconductor wafer (hereinafter, referred to as a “wafer”) which is a substrate, a liquid processing process is provided to process the wafer surface using a liquid, in which for example, minute dust or a natural oxide film on the wafer surface is removed with a cleaning liquid such as, for example, a chemical liquid.

However, with high integration of the semiconductor device, when, for example, the liquid attached to the surface of the wafer is removed in the liquid processing process, a phenomenon so-called a pattern collapse becomes problematic. The pattern collapse refers to a phenomenon in which, when the liquid remaining on the wafer surface is dried, the liquid remaining at left and right sides of, for example, a convex (that is, inside of a concave) of an unevenness forming a pattern is unevenly dried, and then a balance of surface tensions that draw the convex from side to side is lost, and thus, the convex collapses in a direction in which the liquid remains in a large amount.

As a technique for removing the liquid attached to the wafer surface while suppressing occurrence of the pattern collapse, a method using a fluid in a supercritical state or a subcritical state (hereinafter, the states are integrally referred to as a “high-pressure state”) has been known. The fluid (high-pressure fluid) in the high-pressure state is lower in viscosity and higher in capability of extracting the liquid than the liquid. In addition, no interface exists between the high-pressure fluid and the liquid or gas which is in an equilibrium state to the high-pressure fluid. Therefore, when the liquid attached to the wafer surface is substituted with the high-pressure fluid and thereafter, the state of the high-pressure fluid is changed to a gas state, the liquid may be dried without being influenced by the surface tension.

For example, in terms of high replaceability between the liquid and the high-pressure fluid and suppression of inflow of moisture in the liquid processing, Japanese Patent Laid-Open Publication No. 2011-187570 uses hydrofluoro ether (HFE) which is a fluorine-containing organic solvent (described as “fluorine compound” in Japanese Patent Laid-Open Publication No. 2011-187570) for both the dry prevention liquid and the high-pressure fluid. Further, the fluorine-containing organic solvent is suitable for the dry prevention liquid in terms of its flame-retardancy.

Meanwhile, the fluorine-containing organic solvent such as, for example, HFE, hydrofluoro carbon (HFC), perfluoro carbon (PFC), or perfluoro ether (PFE) is more expensive than, for example, isopropyl alcohol (IPA) and a volatile loss during wafer conveyance causes an increase in an operation cost. As a result, after the fluorine-containing organic solvent is used as the dry prevention liquid or the high-pressure fluid, when a mixed liquid of the fluorine containing organic solvent is stored and is used through separation and regeneration, the operation cost may be reduced.

In this case, it is considered to store the fluorine-containing organic solvent separated from the mixed liquid in a tank of an atmospheric opening system. However, when the fluorine-containing organic solvent is stored in the tank of the atmospheric opening system, the fluorine-containing organic solvent is discharged to the outside from the tank, and thus, the fluorine-containing organic solvent is lost by that amount.

### SUMMARY

The present disclosure provides a separation and regeneration apparatus including: a mixed liquid generating unit of an atmospheric opening system which is configured to generate a mixed liquid which includes a low-specific-gravity liquid insoluble in a fluorine-containing organic solvent, a first fluorine-containing organic solvent having a first boiling point, and a second fluorine-containing organic solvent having a second boiling point higher than the first boiling point; a distillation tank including a heater configured to heat the first fluorine-containing organic solvent and the second fluorine-containing organic solvent in the mixed liquid up to a temperature between the first boiling point and the second boiling point, the distillation tank being configured to separate the first fluorine-containing organic solvent and the second fluorine-containing organic solvent into the first fluorine-containing organic solvent in a gas state and the second fluorine-containing organic solvent in a liquid state; a first tank configured to liquefy and store the first fluorine-containing organic solvent in the gas state which flows from the distillation tank; and a second tank configured to store the second fluorine-containing organic solvent in the liquid state which flows from the distillation tank, in which surplus pressure return lines are provided between the first tank and the mixed liquid generating unit, and between the second tank and the mixed liquid generating unit, respectively, to return a surplus pressure from each of the first tank and the second tank to the mixed liquid generating unit, and a distal end of each of the surplus pressure return lines is located below the low-specific-gravity liquid in the mixed liquid within the mixed liquid generating unit.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a horizontal plan view of a liquid processing apparatus.

FIG. 2 is a vertical side view of a liquid processing unit provided in the liquid processing apparatus.

FIG. 3 is a configuration diagram of a supercritical processing unit provided in the liquid processing apparatus.

FIG. 4 is an exterior perspective view of a processing container of the supercritical processing unit.

FIG. 5 is a schematic systematic diagram illustrating a separation and regeneration apparatus according to an exemplary embodiment.

FIG. 6 is a diagram illustrating an operation sequence of the exemplary embodiment.

FIG. 7 is a view illustrating details of a mixed drainage liquid tank.

FIG. 8 is a view illustrating usage forms of HFE7300 and FC43.

FIG. 9 is a view illustrating a separation and regeneration apparatus as a comparative example.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The present disclosure was made in consideration of the problems described above and an object of the present disclosure is to provide a separation and regeneration apparatus and a substrate processing apparatus in which a fluorine-containing organic solvent used for removing a liquid attached to the surface of a processing target object is used through separation and regeneration, and thus a reduction of an operation cost is achieved.

According to an aspect of the present disclosure, a separation and regeneration apparatus includes: a mixed liquid generating unit of an atmospheric opening system which is configured to generate a mixed liquid which includes a low-specific-gravity liquid insoluble in a fluorine-containing organic solvent, a first fluorine-containing organic solvent having a first boiling point, and a second fluorine-containing organic solvent having a second boiling point higher than the first boiling point; a distillation tank including a heater configured to heat the first fluorine-containing organic solvent and the second fluorine-containing organic solvent in the mixed liquid up to a temperature between the first boiling point and the second boiling point, the distillation tank being configured to separate the first fluorine-containing organic solvent and the second fluorine-containing organic solvent into the first fluorine-containing organic solvent in a gas state and the second fluorine-containing organic solvent in a liquid state; a first tank configured to liquefy and store the first fluorine-containing organic solvent in the gas state which flows from the distillation tank; and a second tank configured to store the second fluorine-containing organic solvent in the liquid state which flows from the distillation tank, in which surplus pressure return lines are provided between the first tank and the mixed liquid generating unit, and between the second tank and the mixed liquid generating unit, respectively, to return a surplus pressure from each of the first tank and the second tank to the mixed liquid generating unit, and a distal end of each of the surplus pressure return lines is located below the low-specific-gravity liquid in the mixed liquid within the mixed liquid generating unit.

In the separation and regeneration apparatus, an oil-water separator is provided between the mixed liquid generating unit and the distillation tank to separate the mixed liquid into the low-specific-gravity liquid, and the first fluorine-containing organic solvent and the second fluorine-containing organic solvent.

In the separation and regeneration apparatus, a check valve is provided in each of the surplus pressure return lines to suppress backflow.

In the separation and regeneration apparatus, the check valve is constituted by a relief vale or a pressure control valve.

In the separation and regeneration apparatus, the first tank and the second tank are provided at a position higher than the mixed liquid generating unit to suppress backflow within each of the surplus pressure return lines.

According to another aspect of the present disclosure, a separation and regeneration apparatus includes: a mixed liquid generating unit configured to generate a mixed liquid which includes a low-specific-gravity liquid insoluble in a fluorine-containing organic solvent, and a fluorine-containing organic solvent; and a buffer tank configured to store the fluorine-containing organic solvent in the mixed liquid, in which a surplus pressure return line is provided between the buffer tank and the mixed liquid generating unit to return a surplus pressure from the buffer tank to the mixed liquid generating unit, and a distal end of the surplus pressure return line is located below the low-specific-gravity liquid in the mixed liquid generating unit

In the separation and regeneration apparatus, an oil-water separator is provided between the mixed liquid generating unit and the buffer tank to separate the mixed liquid into the low-specific-gravity liquid and the fluorine-containing organic solvent.

In the separation and regeneration apparatus, a check valve is provided in the surplus pressure return line to suppress backflow.

In the separation and regeneration apparatus, the check valve is constituted by a relief vale or a pressure control valve.

In the separation and regeneration apparatus, the buffer tank is provided at a position higher than the mixed liquid generating unit to suppress backflow within the surplus pressure return line.

According to a further aspect of the present disclosure, a substrate processing apparatus includes: a liquid processing unit configured to supply a first fluorine-containing organic solvent having a first boiling point and a second fluorine-containing organic solvent having a second boiling point higher than the first boiling point to a processing target object to perform a liquid processing; a supercritical processing unit configured to bring a liquid of fluorine-containing organic solvent attached to the processing target object after the liquid processing into contact with a supercritical fluid of a fluorine-containing organic solvent to remove the liquid; and a substrate conveyance unit configured to convey the processing target object, which has been subjected to the liquid processing in the liquid processing unit, to the supercritical processing unit. The separation and regeneration apparatus described above is included in at least one of the liquid processing unit and the supercritical processing unit.

According to the present exemplary embodiment, the fluorine-containing organic solvent, which has been used for inhibiting a pattern collapse by certainly removing the liquid attached to the surface of the processing target object, is used through separation and regeneration, and thus a reduction of an operation cost is achieved.

<Substrate Processing Apparatus>

First, a substrate processing apparatus embedded with a separation and regeneration apparatus according to the present disclosure will be described. As one example of the substrate processing apparatus, a liquid processing apparatus 1 will be described, which includes a liquid processing unit 2 configured to perform a liquid processing by supplying various processing liquids to a wafer W (a processing target object) which is a substrate and a supercritical processing unit (high-pressure fluid processing unit) 3 configured to remove a dry prevention liquid, which is attached on the wafer W after the liquid processing, by bringing the dry prevention liquid into contact with a supercritical fluid (high-pressure fluid).

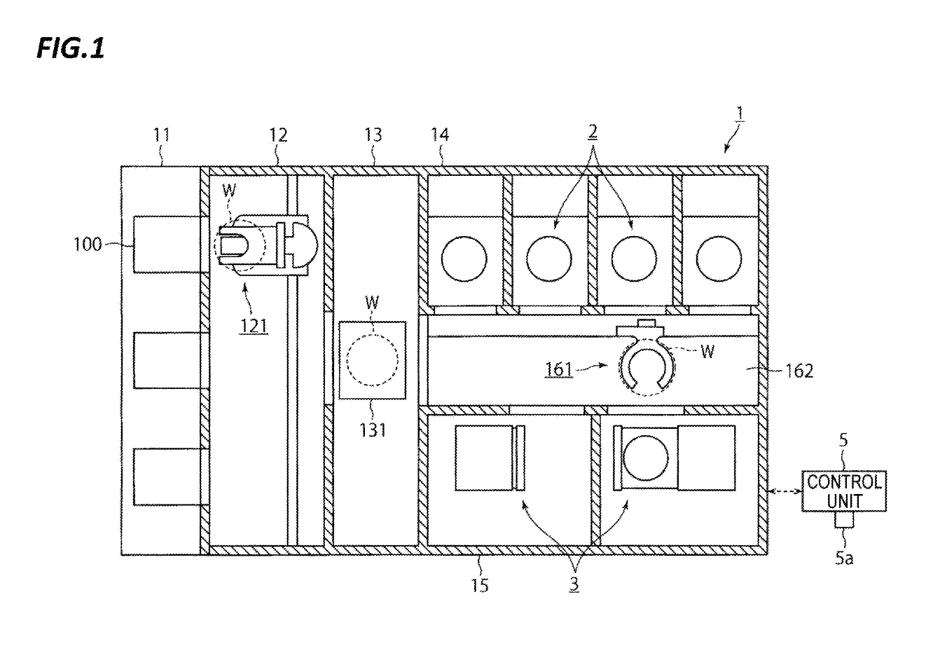

FIG. 1 is a horizontal plan view illustrating an overall configuration of the liquid processing apparatus 1. A left side of the drawing is set as a front side. In the liquid processing apparatus 1, a FOUP 100 is placed in a disposition unit 11. For example, a plurality of wafers W having a diameter of 300 mm accommodated in the FOUP 100 is delivered to/from a liquid processing section 14 and a supercritical processing section 15 at a latter stage through a carry-in/out section 12 and a delivery section 13, and is sequentially carried into the liquid processing unit 2 and the supercritical processing unit 3 so that a liquid processing or a processing of removing the dry prevention liquid is performed. In the drawing, reference numeral 121 represents a first conveyance mechanism that conveys the wafer W between the FOUP 100 and the delivery section 13, and reference numeral 131 is a delivery shelf serving as a buffer in which the wafer W conveyed between the carry-in/out section 12 and the liquid processing section 14, and the supercritical processing section 15 is temporarily placed.

The liquid processing section 14 and the supercritical processing section 15 are provided across a conveyance space 162 of the wafer W. The conveyance space 162 extends in a forward-backward direction from an opening between the delivery section 13 and the conveyance space 162. For example, four liquid processing units 2 are disposed along the conveyance space 162 in the liquid processing section 14 formed at a left side of the conveyance space 162 when viewed from the front side. Meanwhile, for example, two supercritical processing units 3 are disposed along the conveyance space 162 in the supercritical processing section 15 provided at a right side of the conveyance space 162.

The wafers W are conveyed among the liquid processing units 2, the supercritical processing units 3, and the delivery section 13 by a second conveyance mechanism 161 disposed on the conveyance space 162 for the wafers. The second conveyance mechanism 161 corresponds to a substrate conveyance unit. Herein, the number of the liquid processing units 2 or the supercritical processing units 3 disposed in the liquid processing section 14 or the supercritical processing section 15 is appropriately selected according to, for example, the number of wafers W processed per unit time or a difference in processing time between the liquid processing unit 2 and the supercritical processing unit 3, and an optimal layout is selected according to, for example, the number of the liquid processing units 2 or the supercritical processing units 3 that are disposed.

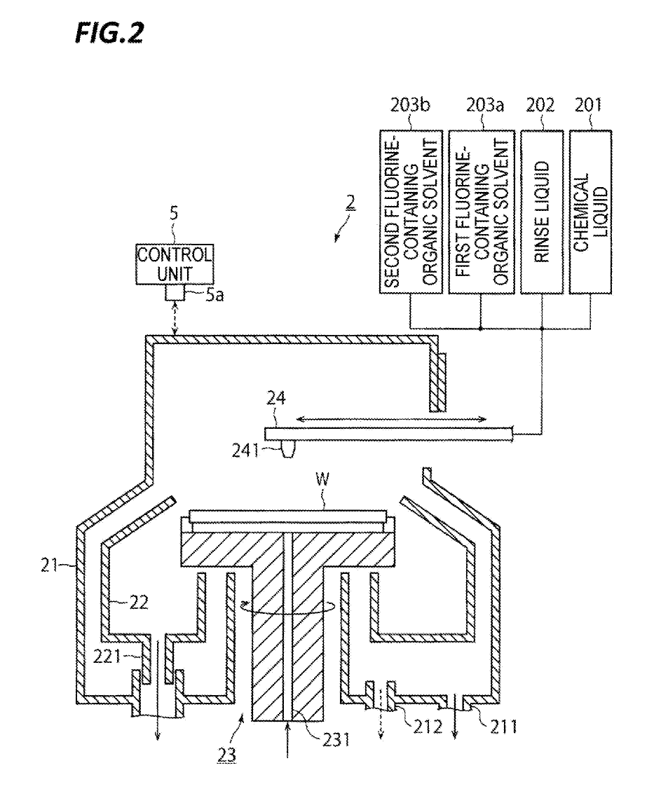

The liquid processing unit 2 is constituted by, for example, the single wafer-type liquid processing unit 2 that cleans the wafers W one by one by spin cleaning, and as illustrated in the vertical side view of FIG. 2, includes an outer chamber 21 that forms a processing space, a wafer holding mechanism 23 disposed in the outer chamber and configured to rotate the wafer W around a vertical axis while substantially horizontally holding the wafer W, an inner cup 22 disposed to surround the wafer holding mechanism 23 from a side circumference and configured to receive a liquid scattered from the wafer W, and a nozzle arm 24 configured to move between a position above the wafer W and a position retreated from the position above the wafer W and having a nozzle 241 provided at a distal end thereof.

A processing liquid supplying unit 201 configured to supply various chemical liquids or a rinse liquid supplying unit 202 configured to supply a rinse liquid, and a first fluorine-containing organic solvent supplying unit 203a (first organic solvent supplying unit) configured to supply a first fluorine-containing organic solvent which is the dry prevention liquid to the surface of the wafer W, and a second fluorine-containing organic solvent supplying unit 203b (second organic solvent supplying unit) configured to supply a second fluorine-containing organic solvent are connected to the nozzle 241. As for the first and second fluorine-containing organic solvents, different solvents from a fluorine-containing organic solvent used for a supercritical processing to be described below are used and further, solvents having a predetermined relationship in terms of the boiling point or threshold temperature are employed as the first fluorine-containing organic solvent, the second fluorine-containing organic solvent and the supercritical processing fluorine-containing organic solvent, but a detailed description thereof will be described below.

A chemical liquid supply path 231 is formed even in the wafer holding mechanism 23 and a rear surface of the wafer W may be cleaned by the chemical liquid and the rinse liquid supplied from the chemical liquid supply path 231. An exhaust port 212 for exhausting an internal atmosphere or liquid discharge ports 221 and 211 for discharging the liquid scattered from the wafer W are formed on the bottom of the outer chamber 21 or the inner cup 22.

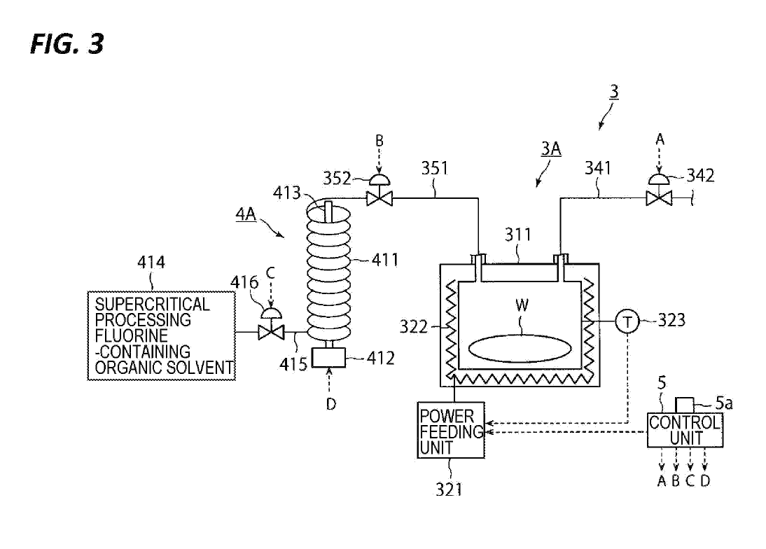

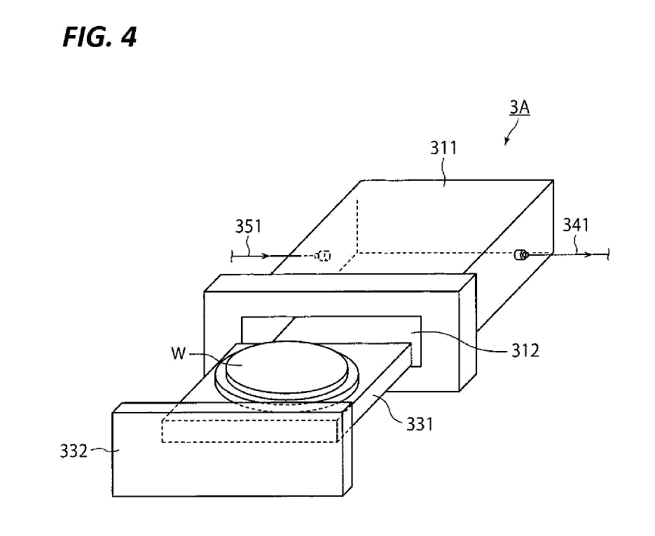

The first fluorine-containing organic solvent for the dry prevention and the second fluorine-containing organic solvent are supplied to the wafer W which has been subjected to a liquid processing in the liquid processing unit 2 and the wafer W is conveyed to the supercritical processing unit 3 by the second conveyance mechanism 161 with the surface of the wafer W being covered with the second fluorine-containing organic solvent. In the supercritical processing unit 3, the wafer W comes in contact with a supercritical fluid of the supercritical processing fluorine-containing organic solvent so that the second fluorine-containing organic solvent is removed and the wafer W is dried. Hereinafter, a configuration of the supercritical processing unit 3 will be described with reference to FIGS. 3 and 4.

The supercritical processing unit 3 includes a processing container 3A in which the dry prevention liquid (second fluorine-containing organic solvent) attached to the surface of the wafer W is removed, and a supercritical fluid supplying unit (supercritical processing organic solvent supplying unit) 4A configured to supply the supercritical fluid of the supercritical processing fluorine-containing organic solvent to the processing container 3A.

As illustrated in FIG. 4, the processing container 3A includes a case type container body 311 formed with an opening 312 for carry-in/out of the wafer W, a wafer tray 331 capable of holding the wafer W to be processed in a transverse direction, and a cover member 332 configured to support the wafer tray 331 and seal the opening 312 when the wafer W is carried into the container body 311.

The container body 311 is, for example, a container having a processing space with a volume of approximately 200 cm³ to 10000 cm³, which is capable of accommodating the wafer W having a diameter of 300 mm. A supercritical fluid supply line 351 for supplying the supercritical fluid into the processing container 3A and a discharge line (discharge unit) 341 for discharging the fluid in the processing container 3A are connected to the top of the container body 311. An opening/closing valve 342 is interposed in the discharge line 341. Further, a pressing mechanism (not illustrated) configured to seal the processing space by pushing the cover member 332 toward the container body 311 against internal pressure caused by a high-pressure processing fluid supplied into the processing space is provided in the processing container 3A.

For example, a heater 322 which is a heating unit constituted by, for example, a resistance heating element, and a temperature detecting unit 323 including, for example, a thermocouple for detecting a temperature in the processing container 3A are provided in the container body 311. The temperature in the processing container 3A is heated to a predetermined temperature by heating the container body 311 and thus, the wafer W within the processing container 3A may be heated. The heater 322 may change a caloric value by changing a power supplied from a power feeding unit 321 and control the temperature in the processing container 3A to a predetermined temperature based on the temperature detection result acquired from the temperature detecting unit 323.

The supercritical fluid supplying unit 4A is connected to an upstream side of the supercritical fluid supply line 351 interposed with an opening/closing valve 352. The supercritical fluid supplying unit 4A includes a spiral pipe 411 which is a pipe for preparing the supercritical fluid of the supercritical processing fluorine-containing organic solvent to be supplied to the processing container 3A, a supercritical processing fluorine-containing organic solvent supplying unit 414 configured to supply the liquid of the supercritical processing fluorine-containing organic solvent which is a raw material of the supercritical fluid to the spiral pipe 411, and a halogen lamp 413 configured to heat the spiral pipe 411 so that the supercritical processing fluorine-containing organic solvent within the spiral pipe 411 may be placed in a supercritical state.

The spiral pipe 411 is, for example, a cylindrical container formed by spirally winding a stainless pipe member in the longitudinal direction thereof and is painted with, for example, a black radiant heat absorption paint in order to easily absorb radiant heat supplied from the halogen lamp 413. The halogen lamp 413 is disposed spaced apart from an inner wall surface of the spiral pipe 411 along a cylindrical central axis of the spiral pipe 411. A power supply unit 412 is connected to a lower end of the halogen lamp 413, and the halogen lamp 413 emits heat by a power supplied from the power supply unit 412 so that the spiral pipe 411 is heated primarily by using the radiant heat. The power supply unit 412 is connected with a temperature detecting unit (not illustrated) provided in the spiral pipe 411 and increases or decreases the power supplied to the spiral pipe 411 based on a detection temperature to heat the inside of the spiral pipe 411 at a predetermined temperature.

Further, a pipe member extends from the lower end of the spiral pipe 411 to form a reception line 415 of the supercritical processing fluorine-containing organic solvent. The reception line 415 is connected to the supercritical processing fluorine-containing organic solvent supplying unit 414 through an opening/closing valve 416 having pressure resistance. The supercritical processing fluorine-containing organic solvent supplying unit 414 includes, for example, a tank configured to store the supercritical processing fluorine-containing organic solvent in a liquid state or a liquid feeding pump, a flow rate control mechanism.

The liquid processing apparatus 1 including the liquid processing unit 2 or the supercritical processing unit 3 configured as described above is connected to a control unit 5 as illustrated in FIGS. 1 to 3. The control unit 5 is constituted by a computer including a CPU (not illustrated) and a memory unit 5a. The memory unit 5a memorizes a program in which a group of steps (commands) on a control associated with operations of the liquid processing apparatus 1 is incorporated. That is, the operations include extracting the wafer W from the FOUP 100 and performing the liquid processing of the extracted wafer W in the liquid processing unit 2 and subsequently, drying the wafer W in the supercritical processing unit 3, and carrying the wafer W into the FOUP 100. The program is stored in memory media such as, for example, a hard disk, a compact disk, a magneto optical disk, and a memory card and then installed into the computer therefrom.

Next, descriptions will be made on the first fluorine-containing organic solvent and the second fluorine-containing organic solvent supplied to the surface of the wafer W in the liquid processing unit 2, and the supercritical processing fluorine-containing organic solvent supplied to the processing container 3A in the state of the supercritical fluid in order to remove the second fluorine-containing organic solvent from the surface of the wafer W. All of the first fluorine-containing organic solvent, the second fluorine-containing organic solvent, and the supercritical processing fluorine-containing organic solvent are fluorine-containing organic solvents including fluorine atoms in hydrocarbon molecules.

An example of a combination of the first fluorine-containing organic solvent, the second fluorine-containing organic solvent and the supercritical processing fluorine-containing organic solvent is illustrated in Table 1.

TABLE 1

| | Maker | Product Name | Class Name | Boiling Point (° C.) |
|---|---|---|---|---|
| First fluorine- | Asahi Garasu | AE-3000 | HFE | 56 |
| containing organic | Kabushiki Kaisha | | | |
| solvent | Asahi Garasu | AC-6000 | HFC | 115 |
| | Kabushiki Kaisha | | | |
| | Asahi Garasu | AC-2000 | HFC | 68 |
| | Kabushiki Kaisha | | | |
| | Sumitomo 3M | Novec (registered | HFE | 61 |
| | Kabushiki Kaisha | trademark) 7100 | | |
| | Sumitomo 3M | Novec (registered | HFE | 76 |
| | Kabushiki Kaisha | trademark) 7200 | | |
| | Sumitomo 3M | Novec (registered | HFE | 98 |
| | Kabushiki Kaisha | trademark) 7300 | | |
| | Sumitomo 3M | Novec (registered | HFE | 128 |
| | Kabushiki Kaisha | trademark) 7500 | | |
| Second fluorine- | Sumitomo 3M | Fluorinert (registered | PFC | 165 |
| containing organic | Kabushiki Kaisha | trademark) FC-40 | | |
| solvent | Sumitomo 3M | Fluorinert (registered | PFC | 174 |
| | Kabushiki Kaisha | trademark) FC-43 | | |
| | Sumitomo 3M | Fluorinert (registered | PFC | 128 |
| | Kabushiki Kaisha | trademark) FC-3283 | | |
| | Solvay Solexis | GALDEN (registered | PFE | 200 |
| | Kabushiki Kaisha | trademark) HT200 | | |
| | Solvay Solexis | GALDEN (registered | PFE | 170 |
| | Kabushiki Kaisha | trademark) | | |
| Supercritical | Sumitomo 3M | Fluorinert (registered | PFC | 56 |
| processing fluorine- | Kabushiki Kaisha | trademark) FC-72 | | |
| containing organic | | | | |
| solvent | | | | |

Among class names of Table 1, hydrofluoro ether (HFE) is a fluorine-containing organic solvent acquired by replacing some hydrogen of hydrocarbon having an ether bond in a molecule with fluorine, and hydrofluoro carbon (HFC) is a fluorine-containing organic solvent acquired by replacing some hydrogen of hydrocarbon with fluorine. Further, perfluoro carbon (PFC) is a fluorine-containing organic solvent acquired by replacing all hydrogen of hydrocarbon with fluorine and perfluoro ether (PFE) is a fluorine-containing organic solvent acquired by replacing all hydrogen of hydrocarbon having an ether bond in the molecule with fluorine.

When one fluorine-containing organic solvent is selected as the supercritical processing fluorine-containing organic solvent among the fluorine-containing organic solvents, another fluorine-containing organic solvent which is higher in a boiling point (lower in vapor pressure) than the supercritical processing fluorine-containing organic solvent is selected as the second fluorine-containing organic solvent. As a result, compared with the case in which the supercritical processing fluorine-containing organic solvent is adopted as the dry prevention liquid, the amount of the fluorine-containing organic solvent volatilized from the surface of the wafer W may be reduced while the wafer W is conveyed to the supercritical processing unit 3 from the liquid processing unit 2.

More appropriately, a boiling point of the first fluorine-containing organic solvent may be about 100° C. (e.g., 98° C.), and a boiling point of the second fluorine-containing organic solvent may be 100° C. or higher (for example, 174° C.), which is higher than that of the first fluorine-containing organic solvent. Since the second fluorine-containing organic solvent having the boiling point of 100° C. or higher is smaller in a volatilization quantity during conveyance of the wafer W, the surface of the wafer W may be maintained in a wet state for approximately dozens of seconds to 10 minutes only by supplying a small amount of fluorine-containing organic solvent, that is, in a small amount of approximately 0.01 cc to 5 cc to a wafer W having a diameter of 300 mm or approximately 0.02 cc to 10 cc to a wafer W having a diameter of 450 mm. For reference, IPA needs to be supplied in an amount of approximately 10 cc to 50 cc to maintain the surface of the wafer W in the wet state for the same time as above.

Further, when two kinds of fluorine-containing organic solvents are selected, high and low values of the boiling point correspond to high and low values of a supercritical temperature. Therefore, as for the supercritical processing fluorine-containing organic solvent used as the supercritical fluid, the fluorine-containing organic solvent which is lower in a boiling point than the second fluorine-containing organic solvent is selected so that a fluorine-containing organic solvent capable of forming the supercritical fluid at a low temperature may be used and the fluorine atoms may be prevented from being released due to decomposition of the fluorine-containing organic solvent.

<Separation and Regeneration Apparatus>

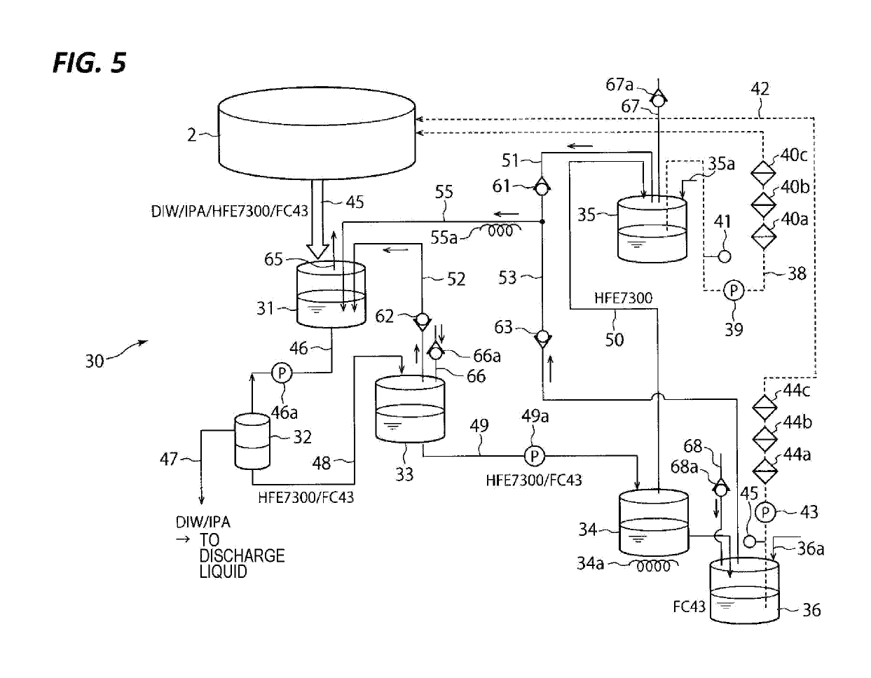

Next, descriptions will be made on the separation and regeneration apparatus according to the present exemplary embodiment, which is incorporated in the substrate processing apparatus, with reference to FIGS. 5 to 9.

As illustrated in FIGS. 5 to 9, a separation and regeneration apparatus 30 includes the above described liquid processing unit 2 configured to accommodate the wafer W, and supply the chemical liquids, the rise liquid, the first fluorine-containing organic solvent, and the second fluorine-containing organic solvent to the wafer W to perform a liquid processing, and a mixed drainage liquid tank 31 of an atmospheric opening system, which is configured to store the drainage liquid from the liquid processing unit 2 and connected to the atmosphere by a discharge line 65. In the mixed drainage liquid tank 31, the drainage liquid (mixed liquid) sent from the liquid processing unit 2 through a discharge line 45 is stored. The mixed liquid includes deionized water (DIW) which is a rinse liquid as described below, IPA, the first fluorine-containing organic solvent, and the second fluorine-containing organic solvent.

The mixed liquid is sent from the mixed drainage liquid tank 31 to an oil-water separator 32 through a supply line 46 attached with a pump 46a. Then, the drainage liquid (mixed liquid) is separated into oil and water by the oil-water separator 32, DIW and IPA are discharged to the outside through a discharge line 47, and the mixed liquid of the first fluorine-containing organic solvent and the second fluorine-containing organic solvent is sent to a buffer tank 33 through a supply line 48.

Then, the mixed liquid of the first fluorine-containing organic solvent and the second fluorine-containing organic solvent is sent from the buffer tank 33 to a distillation tank 34 through a supply line 49 attached with a pump 49a.

The distillation tank 34 separates a first fluorine-containing organic solvent (e.g., HFE7300) having a first boiling point (e.g., 98° C.) and a second fluorine-containing organic solvent (e.g., FC43) having a second boiling point (e.g., 174° C.) higher than the first boiling point in the mixed liquid to generate a gas type first fluorine-containing organic solvent, and a liquid type second fluorine-containing organic solvent. The distillation tank 34 includes a heater 34a configured to heat the mixed liquid, so that the mixed liquid is heated up to a temperature between the first boiling point (e.g., 98° C.) and the second boiling point (e.g., 174° C.), for example, in a range of 120° C. to 150° C. Meanwhile, the first boiling point and the second boiling point are not limited to boiling points at the atmospheric pressure. For example, when the internal pressure of the distillation tank 34 is increased, the boiling point is increased as known, and as a result, the heater 34a may have a temperature between the first boiling point and the second boiling point which are changed.

The gas type first fluorine-containing organic solvent separated in the distillation tank 34 is sent to a first tank 35 through a supply line 50, and is liquefied and stored in the first tank 35.

The liquid type second fluorine-containing organic solvent is sent from the distillation tank 34 to a second tank 36 to be stored.

The first fluorine-containing organic solvent within the first tank 35 is returned to the liquid processing unit 2 through a first supply line 38.

The first supply line 38 is attached with a pump 39, and with an organic matter removing filter 40a including activated carbon, an ion removing filter 40b including activated alumina, and a particle removing filter 40c. A first concentration meter 41 is provided in the first supply line 38.

A surplus pressure return line 51 is connected to the upper portion of the first tank 35 to return a surplus pressure within the first tank 35 to the mixed drainage liquid tank 31. The surplus pressure return line 51 joins to a surplus pressure return line 53 to be described below to be connected to a merging line 55. The merging line 55 reaches the mixed drainage liquid tank 31.

The second fluorine-containing organic solvent within the second tank 36 is returned to the liquid processing unit 2 through a second supply line 42.

The second supply line 42 is attached with a pump 43, and with an organic matter removing filter 44a including activated carbon, an ion removing filter 44b including activated alumina, and a particle removing filter 44c. A second concentration meter 45 is provided in the second supply line 42.

A surplus pressure return line 53 is connected to the upper portion of the second tank 36 to return a surplus pressure within the second tank 36 to the mixed drainage liquid tank 31. The surplus pressure return line 53 joins to the surplus pressure return line 51 to be connected to the merging line 55 which reaches the mixed drainage liquid tank 31 as described above.

A first new supply line 35a and a second new supply line 36a are provided in the first tank 35 and the second tank 36 to supply a new first fluorine-containing organic solvent and a new second fluorine-containing organic solvent, respectively.

As for the first concentration meter 41 and the second concentration meter 45, a specific gravimeter that measures a change in specific gravity corresponding to a change in concentration or an optical measurer that measures a change in refractive index corresponding to the change in concentration may be used.

Further, components of the separation and regeneration apparatus 30, for example, the pumps 46a, 49a, 39, and 43 and the distillation tank 34 are driven and controlled by the control unit 5 having the memory unit 5a.

Hereinafter, further descriptions will be made on the surplus pressure return lines 51 and 53 connected to the first tank 35 and the second tank 36, and the merging line 55.

The surplus pressure return lines 51 and 53 and the merging line 55 return surplus pressures within the first tank 35 and the second tank 36 to the mixed drainage liquid tank 31 of the atmospheric opening system so that the inside of the first tank 35 and the second tank 36 may be maintained at the same pressure as that of the mixed drainage liquid tank 31. Accordingly, the first fluorine-containing organic solvent may be smoothly guided from the distillation tank 34 to the first tank 35, and the second fluorine-containing organic solvent may be smoothly guided from the distillation tank 34 to the second tank 36.

A check valve 61 including a relief valve or a pressure control valve is attached to the surplus pressure return line 51 so as to suppress the mixed liquid from flowing back into the first tank 35 from the mixed drainage liquid tank 31. Also, a check valve 63 including a relief valve or a pressure control valve is attached to the surplus pressure return line 53 so as to suppress the mixed liquid from flowing back into the second tank 36 from the mixed drainage liquid tank 31.

An atmospheric air introducing pipe 67 is provided in the first tank 35 to guide atmospheric air into the first tank 35 when the pressure within the first tank 35 becomes a negative pressure, and a check valve 67a including a relief valve or a pressure control valve is attached to the atmospheric air introducing pipe 67 to suppress the first fluorine-containing organic solvent within the first tank 35 from being discharged to the outside.

An atmospheric air introducing pipe 68 is provided in the second tank 36 to guide atmospheric air into the second tank 36 when the pressure within the second tank 36 becomes a negative pressure, and a check valve 68a including a relief valve or a pressure control valve is attached to the atmospheric air introducing pipe 68 to suppress the second fluorine-containing organic solvent within the second tank 36 from being discharged to the outside.

A heater 55a is attached to the merging line 55, so that the fluorine-containing organic solvent within the merging line 55 may be maintained in a vaporized state by the heater 55a when sent into the mixed drainage liquid tank 31.

Also, a surplus pressure return line 52 is connected to the buffer tank 33 to return a surplus pressure within the buffer tank 33 to the mixed drainage liquid tank 31 of the atmospheric opening system. The surplus pressure within the buffer tank 33 may be returned to the mixed drainage liquid tank 31 through the surplus pressure return line 52 so that the inside of the buffer tank 33 may be maintained at the same pressure as that of the mixed drainage liquid tank 31. Accordingly, the drainage liquid may be smoothly guided from the oil-water separator 32 to the buffer tank 33.

An atmospheric air introducing pipe 66 is provided in the buffer tank 33 to guide atmospheric air into the buffer tank 33 when the pressure within the buffer tank 33 becomes a negative pressure, and a check valve 66a including a relief valve or a pressure control valve is attached to the atmospheric air introducing pipe 66 to suppress the fluorine-containing organic solvent within the buffer tank 33 from being discharged to the outside.

In the example described above, the check valves 61, 63, and 62 are provided in the surplus pressure return lines 51 and 53 introduced from the first and second tanks 35 and 36, and in the surplus pressure return line 52 introduced from the buffer tank 33, respectively, but the present disclosure is not limited thereto. The first tank 35, the second tank 36, and the buffer tank 33 may be disposed at a position higher than the mixed drainage liquid tank 31, and the surplus pressures from the first tank 35, the second tank 36, and the buffer tank 33 may be returned to the mixed drainage liquid tank 31 using lift head. In this case, it is not necessary to provide the check valves 61, 63, and 62 in the surplus pressure return lines 51, 53, and 52.

Among the surplus pressure return line 51 introduced from the first tank 35, the surplus pressure return line 53 introduced from the second tank 36, and the surplus pressure return line 52 introduced from the buffer tank 33, only the surplus pressure return lines 51 and 53 may be provided. In this case, the surplus pressure return line 52 is not required. Otherwise, only the surplus pressure return line 52 may be provided, and in this case, the surplus pressure return lines 51 and 53 are not necessary.

The surplus pressure return lines 51 and 53 introduced from the first tank 35 and the second tank 36 may not join to the merging line 55, but may be guided to the mixed drainage liquid tank 31 independently from each other.

<Operation of Exemplary Embodiment>

Next, an operation of the present exemplary embodiment as configured above will be described.

In the present exemplary embodiment, descriptions will be made on the operation in a case in which HFE7300 is used as the first fluorine-containing organic solvent, FC43 is used as the second fluorine-containing organic solvent, and FC72 is used as the supercritical processing fluorine-containing organic solvent.

First, the wafer W extracted from the FOUP 100 is carried into the liquid processing section 14 through the carry-in/out section 12 and the delivery section 13 and is delivered to the wafer holding mechanism 23 of the liquid processing unit 2. Continuously, various processing liquids are supplied to the surface of the wafer W which rotates to perform a liquid-processing.

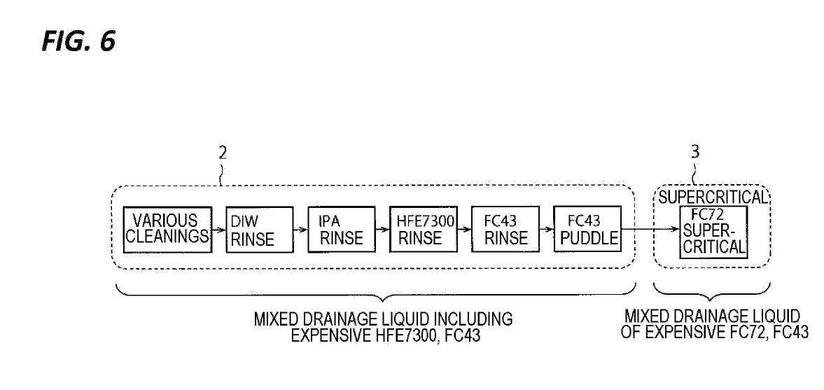

As illustrated in FIG. 6, in the liquid processing, for example, particles or organic pollutant substances are removed by an SC1 liquid (a mixed liquid of ammonia and hydrogen peroxide) which is an alkaline chemical liquid and thereafter, a rinse cleaning is performed by deionized water (DIW) which is a rinse liquid.

When the liquid processing or the rinse cleaning, which uses the chemical liquid, is completed, IPA is supplied from the processing liquid supplying unit 201 to the surface of the rotating wafer W to replace DIW which remains on the top surface and the rear surface of the wafer W. When the liquid on the surface of the wafer W is sufficiently replaced with the IPA, the first fluorine-containing organic solvent (HFE7300) is supplied to the surface of the rotating wafer W from the first fluorine-containing organic solvent supplying unit 203a and thereafter, the rotation of the wafer W stops. Then, the wafer W is rotated, the second fluorine-containing organic solvent (FC43) is supplied to the surface of the rotating wafer W from the second fluorine-containing organic solvent supplying unit 203b and thereafter, and the rotation of the wafer W stops. The surface of the wafer W of which the rotation stops is covered with the second fluorine-containing organic solvent. In this case, since the IPA has high affinity with DIW and HFE7300, and HFE7300 has high affinity with IPA and FC43, DIW may be certainly replaced with IPA and next, IPA may be certainly replaced with HFE7300. Next, HFE7300 may be easily and certainly replaced with FC43.

The wafer W on which the liquid processing has been completed is carried out from the liquid processing unit 2 by the second conveyance mechanism 161 and conveyed to the supercritical processing unit 3. Since the fluorine-containing organic solvent having the high boiling point (the low vapor pressure) is used as the second fluorine-containing organic solvent, the amount of the fluorine-containing organic solvent volatilized from the surface of the wafer W during the conveyance may be reduced.

In a period of time before the wafer W is carried into the processing container 3A, the supercritical fluid supplying unit 4A feeds a predetermined amount of liquid of the supercritical processing fluorine-containing organic solvent from the supercritical processing fluorine-containing organic solvent supplying unit 414 by opening the opening/closing valve 416 and thereafter, seals the spiral pipe 411 by closing the opening/closing valves 352 and 416. In this case, the liquid of the supercritical processing fluorine-containing organic solvent stagnates at the lower side of the spiral pipe 411. A space is left at the upper side of the spiral pipe 411, in which the supercritical processing fluorine-containing organic solvent is expanded when being evaporated by heating.

Then, when the halogen lamp 413 emits heat by initiating a power feeding from the power supply unit 412 to the halogen lamp 413, the inside of the spiral pipe 411 is heated, and as a result, the supercritical processing fluorine-containing organic solvent is evaporated. Then, the temperature and pressure of the supercritical processing fluorine-containing organic solvent increase to reach a threshold temperature and a threshold pressure so that the supercritical processing fluorine-containing organic solvent becomes the supercritical fluid. The temperature and the pressure of the supercritical processing fluorine-containing organic solvent in the spiral pipe 411 rise up to a temperature and a pressure at which the threshold temperature and the threshold pressure may be maintained when the supercritical processing fluorine-containing organic solvent is supplied to the processing container 3A.

By this configuration, the wafer W of which the liquid processing has been completed and the surface is covered with the second fluorine-containing organic solvent is carried into the supercritical processing unit 3 that has been prepared to supply the supercritical fluid of the supercritical processing fluorine-containing organic solvent.

When the wafer W is carried into the processing container 3A and the cover member 332 is closed to seal the processing container 3A as illustrated in FIG. 3, the supercritical fluid of the supercritical processing fluorine-containing organic solvent is supplied from the supercritical fluid supplying unit 4A by opening the opening/closing valve 352 of the supercritical fluid supply line 351 before the second fluorine-containing organic solvent on the surface of the wafer W is dried.

When the supercritical fluid is supplied from the supercritical fluid supplying unit 4A and the inside of the processing container 3A is thus placed in a supercritical fluid atmosphere of the supercritical processing fluorine-containing organic solvent, the opening/closing valve 352 of the supercritical fluid supply line 351 is closed. The supercritical fluid supplying unit 4A turns off the halogen lamp 413, discharges the fluid in the spiral pipe 411 through a depressurization line (not illustrated), and prepares for receiving the supercritical processing fluorine-containing organic solvent in the liquid state from the supercritical processing fluorine-containing organic solvent supplying unit 414 in order to prepare for the subsequent supercritical fluid.

Meanwhile, the supply of the supercritical fluid from the outside to the processing container 3A stops and the inside of the processing container 3A is sealed while being filled with the supercritical fluid of the supercritical processing fluorine-containing organic solvent. In this case, when attention is focused on the surface of the wafer W in the processing container 3A, the supercritical fluid of the supercritical processing fluorine-containing organic solvent is in contact with the liquid of the second fluorine-containing organic solvent that enters a pattern.

When the contact state between the liquid of the second fluorine-containing organic solvent and the supercritical fluid is maintained, the second fluorine-containing organic solvent and the supercritical processing fluorine-containing organic solvent which are highly miscible are mixed with each other and the liquid in the pattern is replaced with the supercritical fluid. Finally, the liquid of the second fluorine-containing organic solvent is removed from the surface of the wafer W and an atmosphere of the supercritical fluid of a mixture of the second fluorine-containing organic solvent and the supercritical processing fluorine-containing organic solvent is formed around the pattern. In this case, since the liquid of the second fluorine-containing organic solvent may be removed at a comparatively low temperature close to the threshold temperature of the supercritical processing fluorine-containing organic solvent, the fluorine-containing organic solvent is hardly decomposed and the amount of generated hydrogen fluoride that causes damage to, for example, the pattern is also small.

By this configuration, when a time required for removing the liquid of the second fluorine-containing organic solvent from the surface of the wafer W has elapsed, the fluorine-containing organic solvent is discharged from the inside of the processing container 3A by opening the opening/closing valve 342 of the discharge line 341. In this case, for example, the amount of the heat supplied from the heater 322 is controlled so as to maintain the inside of the processing container 3A at a temperature equal to or greater than the threshold temperature of the supercritical processing fluorine-containing organic solvent. As a result, the mixed fluid may be discharged in the supercritical state or in the gas state without liquefying the second fluorine-containing organic solvent having the boiling point lower than the threshold temperature of the supercritical processing fluorine-containing organic solvent, and the occurrence of the pattern collapse may be prevented at the time of discharging the fluid.

When the processing by the supercritical fluid is terminated, the wafer W which is dried by removing the liquid is extracted by the second conveyance mechanism 161 and conveyed through a route opposite to that for carrying-in of the wafer W to be accommodated in the FOUP 100, and a series of processings on the wafer W is terminated. The aforementioned processing is continuously performed on the respective wafers W in the FOUP 100 in the liquid processing apparatus 1.

In the meantime, as illustrated in FIG. 5, a drainage liquid is sent from the liquid processing unit 2 into the mixed drainage liquid tank 31. The drainage liquid (mixed liquid) is stored in the mixed drainage liquid tank 31.

The drainage liquid includes DIW, IPA, the first fluorine-containing organic solvent (HFE7300), and the second fluorine-containing organic solvent (FC43). In the drainage liquid within the mixed drainage liquid tank 31, each of HFE7300 and FC43 is included in 15 cc per wafer W. Thus, a mixing ratio of HFE7300 and FC43 is 1:1. In this case, the mixed drainage liquid tank 31 serves as a mixed liquid generating unit configured to generate a mixed liquid which includes a low-specific-gravity liquid which contains DIW and IPA and is not dissolved in a fluorine-containing organic solvent, the first fluorine-containing organic solvent, and the second fluorine-containing organic solvent.

Then, the drainage liquid is sent from the mixed drainage liquid tank 31 to the oil-water separator 32 through the supply line 46 by the pump 46a. Then, the drainage liquid is separated into oil and water in the oil-water separator 32, so that the low-specific-gravity liquid which contains DIW and IPA and is not dissolved in the fluorine-containing organic solvent is discharged to the outside through the discharge line 47, and the mixed liquid of the first fluorine-containing organic solvent and the second fluorine-containing organic solvent is sent to the buffer tank 33 through the supply line 48.

Then, the mixed liquid of the first fluorine-containing organic solvent and the second fluorine-containing organic solvent is sent from the buffer tank 33 to the distillation tank 34 through the supply line 49 by the pump 49a.

The distillation tank 34 separates the first fluorine-containing organic solvent having a first boiling point (e.g., 98° C.) and the second fluorine-containing organic solvent having a second boiling point (e.g., 174° C.) higher than the first boiling point in the mixed liquid through heating by the heater 34a to generate a gas type first fluorine-containing organic solvent, and a liquid type second fluorine-containing organic solvent. In this case, the mixed liquid has a temperature between the first boiling point (e.g., 98° C.) and the second boiling point (e.g., 174° C.), for example, in a range of 120° C. to 150° C. by the heater 34a at atmospheric pressure (1 atm). Meanwhile, the surplus pressure within the buffer tank 33 is returned to the mixed drainage liquid tank 31 by the surplus pressure return line 52.

The gas type first fluorine-containing organic solvent separated in the distillation tank 34 is sent to the first tank 35 through the supply line 50, and is liquefied and stored in the first tank 35.

The liquid type second fluorine-containing organic solvent is sent from the distillation tank 34 to the second tank 36 to be stored.

The first fluorine-containing organic solvent within the first tank 35 is returned to the liquid processing unit 2 through the first supply line 38 by the pump 39. Meanwhile, the first fluorine-containing organic solvent within the first tank 35 is purified by the organic matter removing filter 40a including activated carbon, the ion removing filter 40b including activated alumina, and the particle removing filter 40c provided in the first supply line 38. The concentration of the first fluorine-containing organic solvent is measured by the first concentration meter 41 provided in the first supply line 38. The surplus pressure within the first tank 35 is returned to the mixed drainage liquid tank 31 by the surplus pressure return line 51 and the merging line 55.

The second fluorine-containing organic solvent within the second tank 36 is returned to the liquid processing unit 2 through the second supply line 42 by the pump 43. Meanwhile, the fluorine-containing organic solvent within the second tank 36 is purified by the organic matter removing filter 44a including activated carbon, the ion removing filter 44b including activated alumina, and the particle removing filter 44c provided in the second supply line 42. The concentration of the second fluorine-containing organic solvent is measured by the second concentration meter 45 provided in the second supply line 42.

The surplus pressure within the second tank 36 is returned to the mixed drainage liquid tank 31 by the surplus pressure return line 53 and the merging line 55.

Hereinafter, further descriptions will be made on the behavior of the surplus pressure within the buffer tank 33, the surplus pressure within the first tank 35, and the surplus pressure within the second tank 36.

As described above, the surplus pressure within the buffer tank 33 is returned to the mixed drainage liquid tank 31 through the surplus pressure return line 52. The surplus pressure within the first tank 35, and the surplus pressure within the second tank 36 are returned to the mixed drainage liquid tank 31 through the surplus pressure return lines 51 and 53, respectively, and the merging line 55.

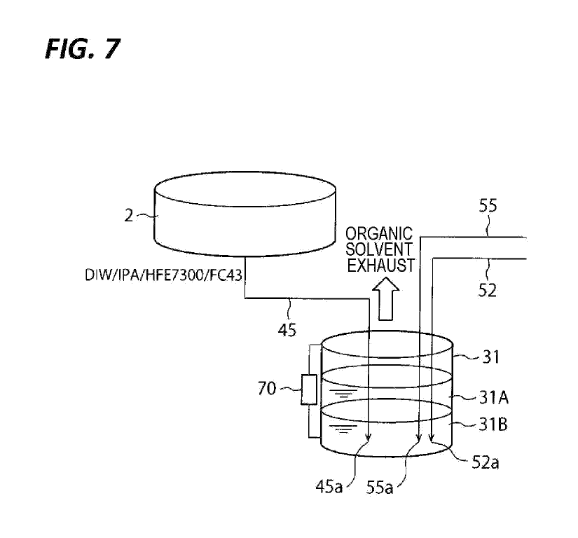

In this case, as illustrated in FIG. 7, the mixed drainage liquid tank 31 is a tank of an atmospheric opening system, and stores, therein, a low-specific-gravity liquid 31A insoluble in a fluorine-containing organic solvent, which contains DIW and IPA, and a fluorine-containing organic solvent 31B which contains the first fluorine-containing organic solvent and the second fluorine-containing organic solvent. For the convenience of description, the term “low-specific-gravity liquid insoluble in a fluorine-containing organic solvent” may be simply referred to as “low-specific-gravity liquid”. The low-specific-gravity liquid 31A in the mixed drainage liquid tank 31 is lighter than the fluorine-containing organic solvent 31B. Thus, in the mixed drainage liquid tank 31, the low-specific-gravity liquid 31A and the fluorine-containing organic solvent 31B are substantially separated, and the low-specific-gravity liquid 31A is located above the fluorine-containing organic solvent 31B.

Both a distal end 52a of the surplus pressure return line 52 introduced from buffer tank 33 and a distal end 55a of the merging line 55 introduced from the first tank 35 and the second tank 36 are located below the low-specific-gravity liquid 31A within the mixed drainage liquid tank 31. Therefore, within the mixed drainage liquid tank 31, the low-specific-gravity liquid 31A serves as a kind of water cover so that the fluorine-containing organic solvent 31B sent from the surplus pressure return line 52 and the merging line 55 may be kept below the low-specific-gravity liquid 31A serving as the water cover.

Surplus pressures may be smoothly guided from the buffer tank 33, the first tank 35 and the second tank 36 to the mixed drainage liquid tank 31 of the atmospheric opening system, and thus, the inside of each of the buffer tank 33, the first tank 35 and the second tank 36 may be maintained at substantially the same pressure as that of the mixed drainage liquid tank 31.

As illustrated in FIG. 7, a distal end 45a of the discharge line 45 introduced from the liquid processing unit 2 is also located below the low-specific-gravity liquid 31A in the mixed drainage liquid tank 31.

In the mixed drainage liquid tank 31, the liquid level of the low-specific-gravity liquid 31A is detected by a liquid level sensor 70 so that the distal end 52a of the surplus pressure return line 52, the distal end 55a of the merging line 55, and the distal end 45a of the discharge line 45 are securely located below the low-specific-gravity liquid 31A. In this case, the distance from the liquid level of the low-specific-gravity liquid 31A detected by the liquid level sensor 70 to each of the distal end 52a of the surplus pressure return line 52 and the distal end 55a of the merging line 55 becomes an internal pressure of each of the buffer tank 33, the first tank 35 and the second tank 36. Accordingly, the liquid level of the low-specific-gravity liquid 31A is preferably adjusted to be as low as possible in order to smoothly guide the surplus pressures within the buffer tank 33, the first tank 35 and the second tank 36 into the mixed drainage liquid tank 31.

In this case, for example, a float may be provided in each of the surplus pressure return line 52 and the merging line 55 so that the pressure within each of the surplus pressure return line 52 and the merging line 55 may be adjusted to be constant.

As described above, the surplus pressure may be guided from each of the buffer tank 33, the first tank 35 and the second tank 36 to the mixed drainage liquid tank 31 so that the inside of each of the buffer tank 33, the first tank 35 and the second tank 36 may be maintained at substantially the same pressure as that of the mixed drainage liquid tank 31 of the atmospheric opening system. The mixed liquid of the fluorine-containing organic solvent may be smoothly guided from the oil-water separator 32 to the buffer tank 33, and the gas type first fluorine-containing organic solvent may be smoothly guided from the distillation tank 34 to the first tank 35. Also, the liquid type second fluorine-containing organic solvent may be smoothly guided from the distillation tank 34 to the second tank 36.

Since the surplus pressure may be guided from each of the buffer tank 33, the first tank 35 and the second tank 36 to the mixed drainage liquid tank 31, the fluorine-containing organic solvent within the buffer tank 33, the first tank 35 and the second tank 36 may be returned to the mixed drainage liquid tank 31 unlike a case where each of the buffer tank 33, the first tank 35 and the second tank 36 is, for example, a tank of an atmospheric opening system. Then, the fluorine-containing organic solvent in the surplus pressure may be effectively used.

In the mixed drainage liquid tank 31, the surplus pressure including the fluorine-containing organic solvent returned from each of the buffer tank 33, the first tank 35 and the second tank 36 is sent to the lower side of the low-specific-gravity liquid 31A. Therefore, although the fluorine-containing organic solvent is exhausted from the mixed drainage liquid tank 31, the amount of the exhausted fluorine-containing organic solvent may be reduced.

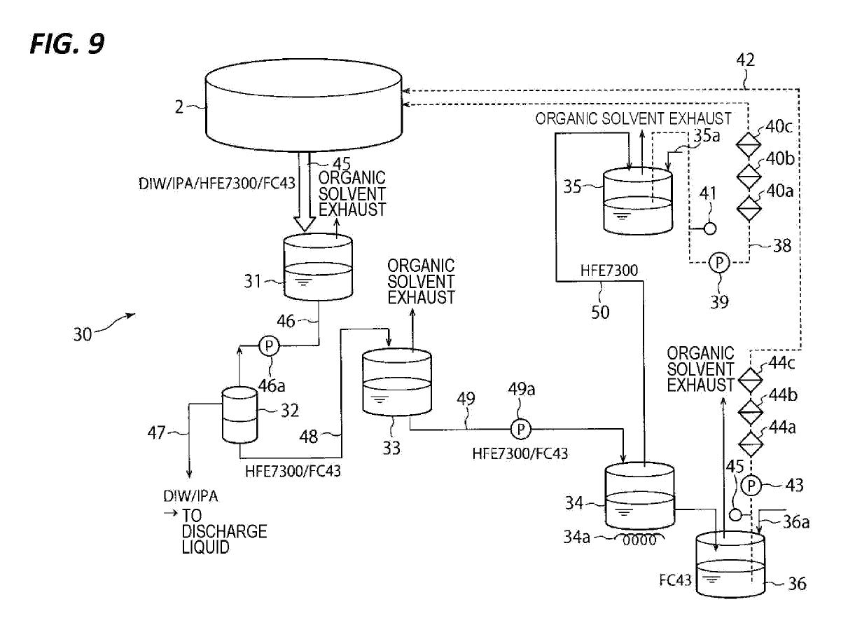

A comparative example of the present disclosure will be described with reference to FIG. 9. In the comparative example illustrated in FIG. 9, each of the buffer tank 33, the first tank 35 and the second tank 36 is constituted by a tank of an atmospheric opening system without being provided with a surplus pressure return line, and other components are almost the same as those of the structure illustrated in FIG. 5.

In the comparative example illustrated in FIG. 9, each of the buffer tank 33, the first tank 35 and the second tank 36 is constituted by the tank of the atmospheric opening system, and thus the surplus pressure including the fluorine-containing organic solvent within each of the buffer tank 33, the first tank 35 and the second tank 36, as it is, is opened to the atmosphere.

In contrast, according to the present exemplary embodiment, the surplus pressure including the fluorine-containing organic solvent within each of the buffer tank 33, the first tank 35 and the second tank 36 may be returned to the mixed drainage liquid tank 31 so that the fluorine-containing organic solvent in the surplus pressure may be effectively used. Further, in the mixed drainage liquid tank 31, the fluorine-containing organic solvent in the surplus pressure is guided to the lower side of the low-specific-gravity liquid 31A. Therefore, the amount of the fluorine-containing organic solvent exhausted from the mixed drainage liquid tank 31 may be further reduced.

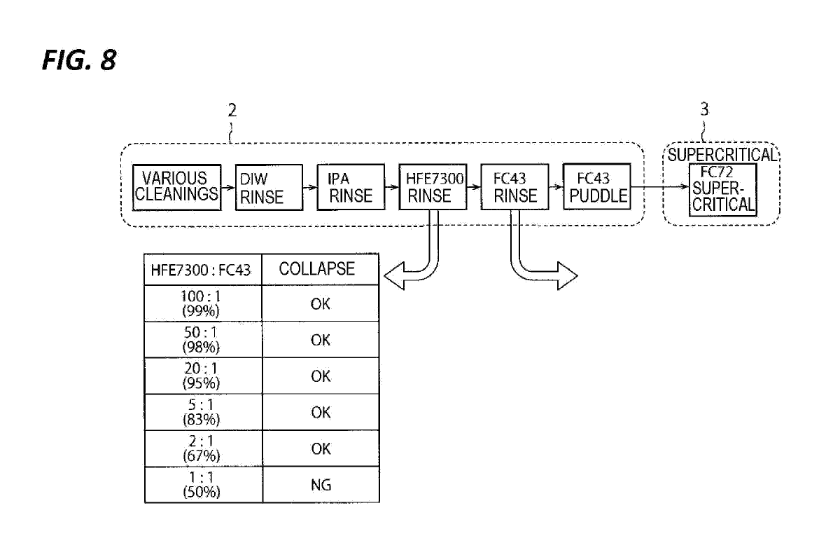

Hereinafter, descriptions will be made on a relationship between a mixing ratio of the mixed liquid including the first fluorine-containing organic solvent (HFE7300) and the second fluorine-containing organic solvent (FC43) in the buffer tank 33, and a separation ratio of the separation of the mixed liquid in the distillation tank 34, with reference to FIG. 8.

As described above, in the drainage liquid within the mixed drainage liquid tank 31, each of HFE7300 and FC43 is included in 15 cc per wafer W. Thus, a mixing ratio of HFE7300 and FC43 is 1:1. Also, in the buffer tank 33, a mixing ratio of HFE7300 and FC43 is also 1:1.

Within the distillation tank 34, the mixed liquid is heated by the heater 34a to be separated into the gas type HFE7300 and the liquid type FC43. The separation ratio corresponds to the mixing ratio of the mixed liquid, that is, 1:1.

Within the distillation tank 34, the mixed liquid is separated into the gas type HFE7300 and the liquid type FC43 in a separation ratio of 1:1 to generate 15 cc of HFE7300 and 15 cc of FC43 per wafer W. In this case, when the purity of HFE7300 separated in the distillation tank 34 is, for example, 86%, the purity of FC43 separated in the distillation tank 34 is also 86% because the mixing ratio of HFE7300 and FC43 is 1:1.

Therefore, HFE7300 with purity of 86% is returned in an amount of 15 cc per wafer W to the liquid processing unit 2 from the first tank 35, and FC43 with purity of 86% is returned in an amount of 15 cc per wafer W to the liquid processing unit 2 from the second tank 36.

In this case, within the liquid processing unit 2, first, HFE7300 with purity of 86% is supplied as the first fluorine-containing organic solvent to the wafer W, and then, FC43 with purity of 86% is supplied as the second fluorine-containing organic solvent to the wafer W.

As illustrated in FIG. 8, when HFE7300 (the rest FC43) with purity of 86% is supplied to the wafer W, there is no problem at all because if the purity of HFE7300 is 67% or more, the pattern collapse does not occur. Then, when FC43 (the rest HFE7300) with purity of 86% is supplied to the wafer W, a sufficient puddle of FC43 may be formed on the wafer W because FC43 and HFE7300 are dissolved with high affinity.

When HFE7300 in an amount of 30 cc per wafer W and FC43 in an amount of 15 cc per wafer W are mixed in a mixing ratio of 2:1 within the buffer tank 33, a separation ratio within the distillation tank 34 is also 2:1.

In this case, when the purity of HFE7300 separated within the distillation tank 34 is, for example, 90%, the purity of FC43 becomes 80%. Here, in the liquid processing unit 2, HFE7300 with purity of 90% is supplied in 30 cc to the wafer W, and then FC43 with purity of 80% is supplied in 15 cc to the wafer W. Since HFE7300 supplied to the wafer W has a purity of 90%, the pattern collapse does not occur. Then, when FC43 with purity of 80% is supplied to the wafer W, a sufficient puddle of FC43 may be formed on the wafer W because FC43 and HFE7300 are dissolved with high affinity.

The present disclosure may be variously modified without being limited to the above described exemplary embodiment. For example, in the above described exemplary embodiment, in the liquid processing unit 2, the first fluorine-containing organic solvent is supplied to the wafer W, and then the second fluorine-containing organic solvent is supplied to the W, but the present disclosure is not limited thereto. In the liquid processing unit 2, after the second fluorine-containing organic solvent is supplied to the wafer W, the first fluorine-containing organic solvent may be supplied to the wafer W. The first fluorine-containing organic solvent and the second fluorine-containing organic solvent may be preferably dissolved with high affinity so that the amount of the fluorine-containing organic solvent volatilized from the surface of the wafer W may be reduced while the wafer W is conveyed to the supercritical processing unit 3 from the liquid processing unit 2.

In the above described exemplary embodiment, water or IPA (alcohol) is used as a low-specific-gravity liquid in generation of a mixed liquid in the mixed liquid generating unit, but the present disclosure is not limited thereto. As for the low-specific-gravity liquid, at least one kind of liquid may be selected from water, alcohol such as, for example, IPA, ketone, ether, and benzene. The low-specific-gravity liquid is not limited to the case where the liquid is supplied to the wafer W, but the liquid may be directly supplied to the mixed drainage liquid tank 31.

In the exemplary embodiment, the liquid processing unit 2 is illustrated, but the present disclosure is not limited thereto. The separation and regeneration apparatus may be employed to separate and regenerate fluorine-containing organic solvents with different boiling points which are discharged from the supercritical processing unit 3. Here, the low-specific-gravity liquid may be supplied in advance to the mixed drainage liquid tank 31 to be stored when the fluorine-containing organic solvents discharged from the supercritical processing unit 3 are sent to the mixed drainage liquid tank 31. Then, the fluorine-containing organic solvents may be discharged into the liquid so as to generate a mixed liquid, and then, the fluorine-containing organic solvents with different boiling points may be separated and regenerated.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A separation and regeneration apparatus comprising:
a mixed liquid generating unit of an atmospheric opening system which is configured to generate a mixed liquid which includes a low-specific-gravity liquid insoluble in a fluorine-containing organic solvent, a first fluorine-containing organic solvent having a first boiling point, and a second fluorine-containing organic solvent having a second boiling point higher than the first boiling point;
a distillation tank including a heater configured to heat the first fluorine-containing organic solvent and the second fluorine-containing organic solvent in the mixed liquid up to a temperature between the first boiling point and the second boiling point, the distillation tank being configured to separate the first fluorine-containing organic solvent and the second fluorine-containing organic solvent into the first fluorine-containing organic solvent in a gas state and the second fluorine-containing organic solvent in a liquid state;
a first tank configured to liquefy and store the first fluorine-containing organic solvent in the gas state which flows from the distillation tank; and
a second tank configured to store the second fluorine-containing organic solvent in the liquid state which flows from the distillation tank,
wherein surplus pressure return lines are provided between the first tank and the mixed liquid generating unit, and between the second tank and the mixed liquid generating unit, respectively, to return a surplus pressure from each of the first tank and the second tank to the mixed liquid generating unit, and a distal end of each of the surplus pressure return lines is located below the low-specific-gravity liquid in the mixed liquid within the mixed liquid generating unit.

2. The separation and regeneration apparatus of claim 1, wherein an oil-water separator is provided between the mixed liquid generating unit and the distillation tank to separate the mixed liquid into the low-specific-gravity liquid, and the first fluorine-containing organic solvent and the second fluorine-containing organic solvent.

3. The separation and regeneration apparatus of claim 1, wherein a check valve is provided in each of the surplus pressure return lines to suppress backflow.

4. The separation and regeneration apparatus of claim 3, wherein the check valve is constituted by a relief vale or a pressure control valve.

5. The separation and regeneration apparatus of claim 1, wherein the first tank and the second tank are provided at a position higher than the mixed liquid generating unit to suppress backflow within each of the surplus pressure return lines.

6. A separation and regeneration apparatus comprising:
a mixed liquid generating unit configured to generate a mixed liquid which includes a low-specific-gravity liquid insoluble in a fluorine-containing organic solvent, and a fluorine-containing organic solvent; and
a buffer tank configured to store the fluorine-containing organic solvent in the mixed liquid,
wherein a surplus pressure return line is provided between the buffer tank and the mixed liquid generating unit to return a surplus pressure from the buffer tank to the mixed liquid generating unit, and a distal end of the surplus pressure return line is located below the low-specific-gravity liquid in the mixed liquid generating unit.

7. The separation and regeneration apparatus of claim 6, wherein an oil-water separator is provided between the mixed liquid generating unit and the buffer tank to separate the mixed liquid into the low-specific-gravity liquid and the fluorine-containing organic solvent.

8. The separation and regeneration apparatus of claim 6, wherein a check valve is provided in the surplus pressure return line to suppress backflow.

9. The separation and regeneration apparatus of claim 8, wherein the check valve is constituted by a relief vale or a pressure control valve.

10. The separation and regeneration apparatus of claim 6, wherein the buffer tank is provided at a position higher than the mixed liquid generating unit to suppress backflow within the surplus pressure return line.

11. A substrate processing apparatus comprising:
a liquid processing unit configured to supply a first fluorine-containing organic solvent having a first boiling point and a second fluorine-containing organic solvent having a second boiling point higher than the first boiling point to a processing target object to perform a liquid processing;
a supercritical processing unit configured to bring a liquid of fluorine-containing organic solvent attached to the processing target object after the liquid processing into contact with a supercritical fluid of a fluorine-containing organic solvent to remove the liquid; and
a substrate conveyance unit configured to convey the processing target object, which has been subjected to the liquid processing in the liquid processing unit, to the supercritical processing unit,
wherein the separation and regeneration apparatus of claim 1 is included in at least one of the liquid processing unit and the supercritical processing unit.
